(19) United States
(12) Patent Application Publication
(10) Pub. No.: US 2014/0239971 A1
(43) Pub. Date: Aug. 28, 2014

(54) DEBUGGING CIRCUIT AND CIRCUIT BOARD USING SAME

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventor: FA-SHENG HUANG, Shenzhen (CN)

(73) Assignees: HONG FU JIN PRECISION INDUSTRY (ShenZhen) CO., LTD., Shenzhen (CN); HON HAI PRECISION INDUSTRY CO., LTD., New Taipei (TW)

(21) Appl. No.: 14/185,017

(22) Filed: Feb. 20, 2014

(30) Foreign Application Priority Data
Feb. 27, 2013 (CN) 2013100604774

(51) Int. Cl. G01R 1/20; G01R 31/317

(52) U.S. Cl. CPC G01R 1/20; G01R 31/31705
USPC 324/537

(57) ABSTRACT

A debugging circuit outputs a plurality of control signals to a chip, the chip outputs a data signal according to the plurality of control signals. The debugging circuit comprises a resistor unit and an adjusting unit. The resistor unit comprises a plurality of resistors, each resistor is electrically connected to one input pin of the chip. The adjusting unit comprises a plurality of control terminals and a switch sub-unit. Each control terminal corresponds to one resistor and one input pin, the switch sub-unit is selectively connected to a first power source or a ground, and the plurality of control terminals output different control signals to the plurality of input pins according to voltage levels of the switch sub-unit

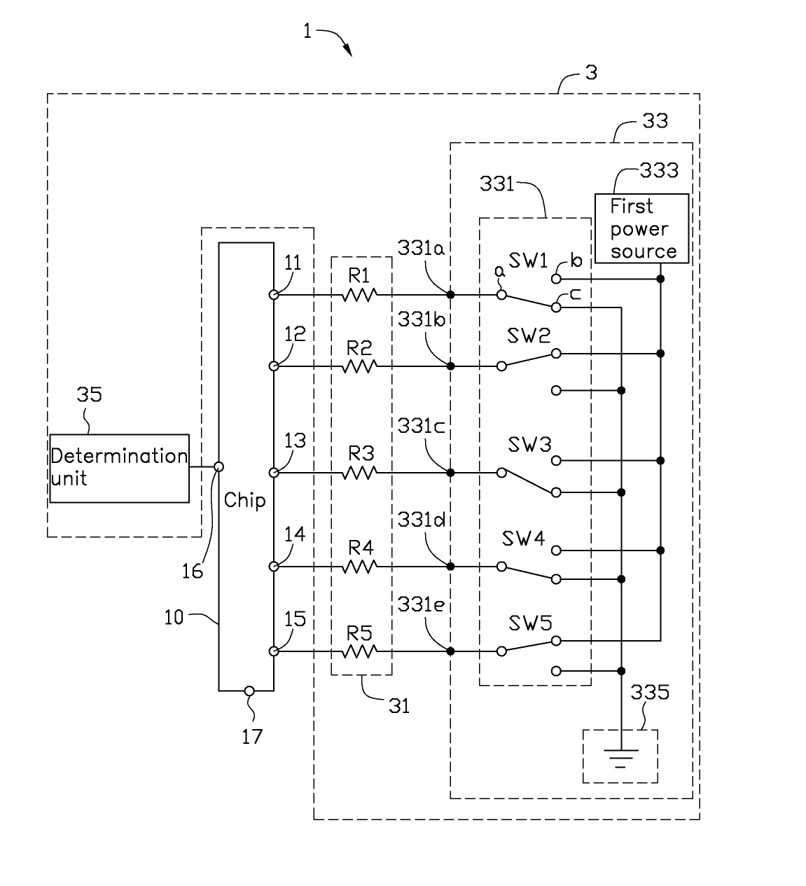

### BACKGROUND

1. Technical Field

The present disclosure relates to a debugging circuit and a circuit board using the debugging circuit.

2. Description of Related Art

In a typical method for debugging a circuit board (e.g. a motherboard) of an electronic device, a plurality of resistors are arranged in a debugging circuit to connect to a plurality of output pins of one or more chips of the circuit board . The plurality of resistors includes pull-up resistors connected to a power source and/or to ground via corresponding pull-down resistors. Signals output by the one or more chips are pulled up by using the pull-up resistors or are pulled down by using the pull-down resistors, and then the pulled-up or pulled-down signals are usually detected to see if requirements are satisfied. However, if a signal which is pulled up or pulled down does not satisfy the requirements, one or more corresponding pull-up resistors and/or pull-down resistors of the debugging circuit need to be changed to re-debug the signal, which is inconvenient and wastes debugging time.

Therefore, what is needed is a means to overcome the above-described shortcoming.

### BRIEF DESCRIPTION OF THE DRAWINGS

The components in the drawings are not necessarily drawn to scale, the emphasis instead being placed upon clearly illustrating the principles of at least one embodiment. In the drawings, like reference numerals designate corresponding parts throughout the various views.

The FIGURE is a circuit diagram of a debugging circuit according to one embodiment.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.” The references “a plurality of” and “a number of” mean “at least two.” Reference will be made to the drawings to describe various embodiments.

The FIGURE shows a circuit diagram of a debugging circuit 3. The debugging circuit 3 is configured to debug signals outputted from a chip 10 arranged on a circuit board 1 (e.g., a motherboard) of an electronic device. The chip 10 comprises a plurality of input pins receiving control signals, and at least one output pin 16 outputting signals. The chip 10 processes or analyzes the received data according to the control signals input from the input pins and then outputs a corresponding signal. In the embodiment, the plurality of input pins comprises a first input pin 11, a second input pin 12, a third input pin 13, a fourth input pin 14, a fifth input pin 15, and a data input pin 17. The chip 10 can be a transceiver between a host controller of the circuit board 1 and a storage device (e.g., a hard disk drive) of the electronic device.

The debugging circuit 3 comprises a resistor unit 31, an adjusting unit 33, and a determination unit 35. The resistor unit 31 comprises a plurality of resistors, and each resistor is configured to connect to one corresponding input pin. In the embodiment, the resistor unit 31 comprises five resistors R1-R5. The first input pin 11 is electrically connected to resistor R1, the second input pin 12 is electrically connected to resistor R2, the third input pin 13 is electrically connected to resistor R3, the fourth input pin 14 is electrically connected to resistor R4, and the fifth input pin 15 is electrically connected to resistor R5.

The adjusting unit 33 comprises a plurality of control terminals, and each control terminal is connected to one corresponding resistor. In the embodiment, the adjusting unit 33 comprises five control terminals 331a-331e, a first power source 333, and a ground 335. The switch sub-unit 331 is selectively connected to the first power source 333 or the ground 335. The first power source 333 and the ground 335 change voltage levels of the five control terminals 331a-331e via the switch sub-unit 331. In the embodiment, the first power source 333 outputs a high level voltage, such as 5V. In the embodiment, the switch sub-unit 331 comprises five single pole double throw (SPDT) switches. Each SPDT switch is electrically connected to one corresponding control terminal. The five SPDT switches include a first SPDT switch SW1, a second SPDT switch SW2, a third SPDT switch SW3, a fourth SPDT switch SW4, and a fifth SPDT switch SW5. Each SPDT switch comprises a first end “a”, a second end “b”, and a third end “c”. The first end “a” is selectively connected to the second “b” or the third end “c”.

The first end “a” is electrically connected to one control terminal, the second end “b” is electrically connected to the first power source 333, and the third end “c” is electrically connected to the ground 335. In detail, the first end “a” of the first SPDT switch SW1 is electrically connected to the control terminal 331a. The first end “a” of the second SPDT switch SW2 is electrically connected to the control terminal 331b. The first end “a” of the third SPDT switch SW3 is electrically connected to the control terminal 331c. The first end “a” of the fourth SPDT switch SW4 is electrically connected to the control terminal 331d. The first end “a” of the fifth SPDT switch SW5 is electrically connected to the control terminal 331e. When the first end “a” is electrically connected to the second end “b”, the first power source 333 outputs the high level voltage to the input pin via the SPDT switch and the resistor, thus the input pin receives a logic high signal (e.g. logic “1”). When the first end “a” is electrically connected to the third end “c”, the input pin is grounded via the corresponding SPDT switch and the corresponding resistor, thus the input pin receives a logic low signal (e.g. logic “0”). In the embodiment, the switch sub-unit 331 is set in an original state, and the first ends “a” of the first SPDT switch SW1, the third SPDT switch SW3, and the fourth SPDT switch SW4 are electrically connected to the third ends “c” of the first SPDT switch SW1, the third SPDT switch SW3, and the fourth SPDT switch SW4, respectively. Thus, the first input pin 11, the third input pin 13, and the fourth input pin 14 receive the logic low signal (e.g. logic “0”). The first ends “a” of the second SPDT switch SW2 and the fifth SPDT switch are electrically connected to the second ends “b” of the second SPDT switch SW2 and the fifth SPDT switch, respectively. Thus, the second input pin 12 and the fifth input pin 15 receive the logic high signal (e.g. logic “1”). The chip 10 outputs the data signal according to the control signals input from the input pins.

The determination unit 35 is electrically connected to the output pin 16. The determination unit 35 determines whether the signal outputted by the output pin 16 satisfies predetermined requirements, such as whether a value of the output data signal is in a predetermined value range. When the data signal satisfies the predetermined requirements, the switch sub-unit 331 remains in the original state. When the data signal does not satisfy the predetermined requirements, the original state of the switch sub-unit 331 is changed via switching a sequence of the SPDT switches to connect to the second power from the first power to control the data signal to satisfy the predetermined requirements.

The debugging circuit 3 can change the state of the switch sub-unit 31 to control the data signal output from the chip 10 is in the predetermined range. Therefore, it is more convenient than rearranging the plurality of resistors.

It is to be understood that even though numerous characteristics and advantages of the present embodiments have been set forth in the foregoing description, with details of the structures and functions of the embodiments, the disclosure is illustrative only; and changes may be in detail, especially in the matters of arrangement of parts within the principles of the embodiments to the full extent indicated by the broad general meaning of the terms in which the appended claims are expressed.

What is claimed is:

1. A debugging circuit for debugging signals outputted from a chip of a circuit board, the debugging circuit comprising:
a resistor unit comprising a plurality of resistors, each resistor electrically connected to one of a plurality of input pins of the chip;
a first power source;
a ground;
an adjusting unit comprising a plurality of control terminals and a switch sub-unit, wherein each control terminal is electrically connected to one corresponding input pin via one corresponding resistor of the plurality of resistors and the switch sub-unit is selectively connected to the first power source or the ground to change control signals outputted by the control terminals; and
a determination unit determining whether signal outputted by the chip according to the control signals satisfying predetermined requirements, when the signals outputted by the chip does not satisfy the predetermined requirements to change control signals to debug the signals outputted by the chip.

2. The debugging circuit of claim 1, wherein the first power source outputs a high level voltage and the ground outputs a low level voltage.

3. The debugging circuit of claim 2, wherein the switch sub-unit comprises a plurality of single pole double throw (SPDT) switches, each SPDT switch comprises a first end, a second end, and a third end; the first end is electrically connected to the corresponding control terminal, the second end is electrically connected to the ground, the third end is electrically connected to the third detection power; and each SPDT switch controls the corresponding control terminal to selectively connected to the first power source or the ground.

4. The debugging circuit of claim 3, wherein when the first end is electrically connected to the second end, the first power source outputs the high level voltage to the input pin via the corresponding SPDT switch and the corresponding resistor, and the input pin receives a logic high signal; when the first end is electrically connected to the third end, the input pin is grounded.

5. The debugging circuit of claim 4, wherein some of the plurality of SPDT switches are set to connect to the first power source, and the other of the plurality of SPDT switches are set to connect to the ground.

6. The debugging circuit of claim 5, wherein when the signal outputted by the chip satisfies the predetermined requirements, the state of the plurality of SPDT switches are not changed when the data signal does not satisfies the predetermined requirements, a sequence of the SPDT switches are switched to connect to the ground from the first power source to control the data signal to satisfy the predetermined requirements.

7. The debugging circuit of claim 6, wherein whether the signal outputted by the output pin satisfies predetermined requirements denotes whether values of the signals are in predetermined value ranges.

8. A circuit board, comprising:
a chip comprising a plurality of inputs pins to receive a plurality of control signals;
a debugging circuit comprising a resistor unit comprising a plurality of resistors, each resistor electrically connected to one of the plurality of input pins of the chip;
a first power source;
a ground;
an adjusting unit comprising a plurality of control terminals and a switch sub-unit, wherein each control terminal is electrically connected to one corresponding input pin via one corresponding resistor of the plurality of resistors, and the switch sub-unit is selectively connected to the first power source or the ground to change control signals outputted by the control terminals; and
a determination unit determining whether signals outputted by the chip according to the control signals satisfying predetermined requirements, when the signals outputted by the chip does not satisfy the predetermined requirements to change control signals to debug the signals outputted by the chip.

9. The circuit board of claim 8, wherein the first power source outputs a high level voltage and the ground outputs a low level voltage.

10. The circuit board of claim 9, wherein the switch sub-unit comprises a plurality of single pole double throw (SPDT) switches, each SPDT switch comprises a first end, a second end, and a third end; the first end is electrically connected to the corresponding control terminal, the second end is electrically connected to the ground, the third end is electrically connected to the third detection power, and each SPDT switch controls the corresponding control terminal to selectively connected to the first power source or the ground.

11. The circuit board of claim 10, wherein when the first end is electrically connected to the second end, the first power source outputs the high level voltage to the input pin via the corresponding SPDT switch and the corresponding resistor, and the input pin receives a logic high signal; when the first end is electrically connected to the third end, the input pin is grounded.

12. The circuit board of claim 11, wherein some of the plurality of SPDT switches are set to connect to the first power source, and the other of the plurality of SPDT switches are set to connect to the ground.

13. The circuit board of claim 12, wherein when the signals outputted by the chip satisfies the predetermined requirements, the state of the plurality of SPDT switches are not changed; when the signals outputted by the chip does not satisfies the predetermined requirements, a sequence of the SPDT switches are switched to connect to the ground from the first power source to control the signals to satisfy the predetermined requirements.

14. The circuit board of claim 13, wherein whether the signals outputted by the output pin satisfies predetermined requirements denotes whether values of the signals are in predetermined value ranges.
